(19) United States
(12) Patent Application Publication
(10) Pub. No.: US 2004/0134770 A1
(43) Pub. Date: Jul. 15, 2004

(54) Ionic plasma deposition apparatus

(76) Inventor: John H Petersen, Longmont, CO (US)

Correspondence Address: MCANDREWS HELD & MALLOY, LTD, 500 WEST MADISON STREET, SUITE 3400, CHICAGO, IL, 60661

(21) Appl. No.: 10/476,527

(22) PCT Filed: Nov. 15, 2002
(86) PCT No.: PCT/US02/36788

(51) Int. Cl. C23C 14/32

(52) U.S. Cl. 204/192.38; 204/298.41

(57) ABSTRACT

A process and apparatus (10) for depositing thin films onto the surface of a substrate (40) using cathodic arc deposition. The process and apparatus (10) include a cathode (14) of target material, disposed within a vacuum chamber (12), which is powered to generate an arc for vaporizing the target material into a plasma of particulate constituents. The plasma constituents are selected, controlled and directed toward the substrate by electromagnetic fields generated by at least a first anode, surrounding the cathode (14), and a second anode positioned adjacent the first anode. Additional anode structures and variable charged screens can also be used to provide further control of the plasma constituents. Use of the process and apparatus (10) to manufacture fuel cells of the type employing catalytic layers, conductive layers, and a polymeric proton exchange membrane is also disclosed.

### RELATED APPLICATIONS

This application claims priority to the following U.S. Provisional Patent Applications: U.S. Provisional Patent Application Serial No. 60/335,689 entitled “Integrated Fuel Cell Components and Process for Making Same”, filed Nov. 15, 2001, the disclosure of which is hereby incorporated by reference and U.S. Provisional Patent Application Serial No. 60/376,893,

entitled “Vacuum Arc Implantation Apparatus and Ionic Plasma Impregnation Apparatus Generated By Vacuum Arc”, filed May 1, 2002, the disclosure of which is incorporated by reference.

### FIELD OF THE INVENTION

This invention relates to a process and an apparatus for depositing thin films on substrates. More particularly, the invention relates to a process and apparatus for controlling the various constituents of the plasma generated by a cathodic arc discharge in order to apply one or more materials onto or into a substrate. Control of the plasma constituents is obtained through the use of controlled or balanced electromagnetic forces generated by the anodes, as well as through the further use of other devices, such as variably charged screens. The apparatus and process are useful for the manufacture of a wide variety of devices, but are particularly useful in the manufacture of fuel cells.

### BACKGROUND

The deposition of thin films of material on a substrate by cathodic arc in a vacuum is known in the art. Such deposition involves establishing an arc in a vacuum, between a cathode formed from the coating material and an anode, which results in the production of a plasma of the cathode material suitable for coating. Although known cathodic are deposition methods are useful for particular applications, they suffer from certain disadvantages. For example, there is a tendency for these methods to coat all system surfaces including the substrate with the material being deposited as only one combination of unknown macro-particles, ions and energetic electrons. Arc confinement schemes require frequent cleaning, contamination problems can occur when the arc spot contacts non-cathode nitrided materials adjacent to the cathode, and a waste of often expensive coating material can occur due to inefficient use of the target material and the lack of particle control essential for reclaiming precious metals. Such processes also form particles of varying sizes which are not selected or controlled, which can lead to the deposition of nonuniform coatings. Typically these processes require the substrate surface to be heated to very high temperatures, which can damage the substrate material and, restrict the choice of substrates.

Various filtering devices have been developed to better control the direction of ionic and electron flow. Such filters include the use of electromagnetic coils of wire or tubing to force the flow in a helical electromagnetic field. Further curvatures and off axis capturing of macro particles accentuates the use of these devices as macro particle filters only. The arc must be scanned or forced around the circular surface of a cathode to achieve enough ionization to make a substantial deposition rate at the substrate. This is due to the crossing fields creating the helical trajectories, which heavily focus the ion stream to the center of a circular anode in which the electrons are forced to converge to a single path down the center of the apparatus.

The art of ion beam bending has shown the advantages of linear field lines to reduce trajectory-oriented losses in gas analysis equipment. Such art highlights the need for better control of the plasma constituents in order to limit trajectory losses and control the resulting trajectories in contrast to the sorting of ions and neutral particles, as in the cathodic arc prior art. Control over each of the plasma constituents improves the method of manufacturing articles employing thin films, especially in the area of large scale fuel cell manufacturing.

Conventional methods for manufacturing electrochemical fuel cells typically involve forming layers of electrically conductive material, such as carbon papers, paints, paste and sputtered layers containing a metal catalyst, such as platinum with a separate polymeric proton exchange membrane, and then extensive methods for bonding the layers together. Such layers can be fairly thick, and thickness of the layers will affect properties such as electrical conductivity and protonic conductivity. Moreover, bonding of the thick layers together can affect the interface properties between the layers, which can increase the surface resistance of the fuel cell, resulting in lower electric and protonic conductivity.

### BRIEF SUMMARY OF THE INVENTION

It is an object of the present invention to provide a vacuum arc plasma deposition process and apparatus than can control the plasma constituents reaching a substrate material.

It is another object of the invention to provide a vacuum arc plasma deposition process and apparatus that is capable of producing nanostructures with variable particle sizes, amorphous continuous films and crystalline structures in multiple layers with the same device.

Another object of the invention is to provide a method of manufacturing fuel cells in which a vacuum arc plasma deposition process and apparatus are used to form the conductive, catalytic and proton exchange membrane layers of the fuel cell.

A further object of the invention is to provide a method for manufacturing fuel cells, which results in the formation of integrated fuel cell layers, thus eliminating the need to employ complex pasting, printing and bonding technologies.

Accordingly, the present invention provides a process and apparatus for depositing thin films onto or into the surface of a substrate wherein, in a vacuum chamber, a cathode of target material is vaporized by an arc generated at the cathode into a plasma of particulate constituents. The plasma constituents are selected, controlled or directed toward the substrate by electromagnetic fields generated by at least a first anode, near the cathode, and a second anode, which is positioned adjacent the first anode. Additional anode structures and variable charged screens are also used to provide further control of the plasma constituents. The process and apparatus can be used to make electrochemical fuel cells of the type employing catalytic layers, conductive layers, a polymeric proton exchange membranes and solid oxide membranes. The control of the plasma constituents greatly improves the ability to define properties for thin films for any purpose.

### BRIEF DESCRIPTION OF THE DRAWINGS

The particular features and advantages of the present invention will become apparent from the following description taken in conjunction with the accompanying drawings which:

FIG. 1 is a diagrammatic view of a general apparatus constructed in accordance with the principles of the present invention;

FIG. 2 is a diagrammatic view of a dual coaxial coil arrangement used in one embodiment of the apparatus of the present invention;

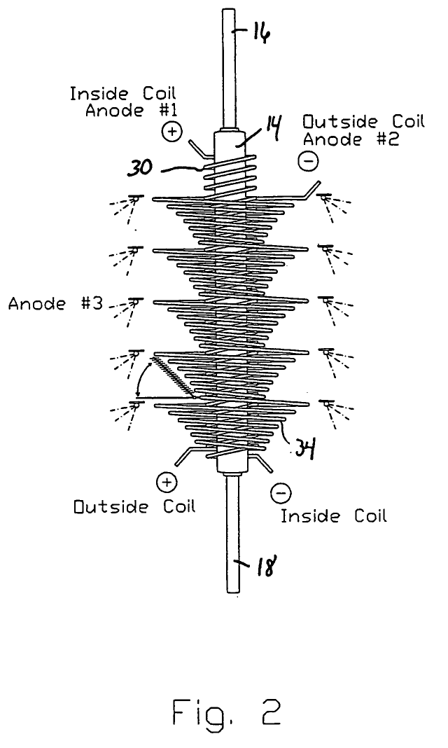

FIG. 3 is a diagrammatic view of the dual coils of FIG. 2 illustrating the arrangement of the coils toward the ends of the cylinder;

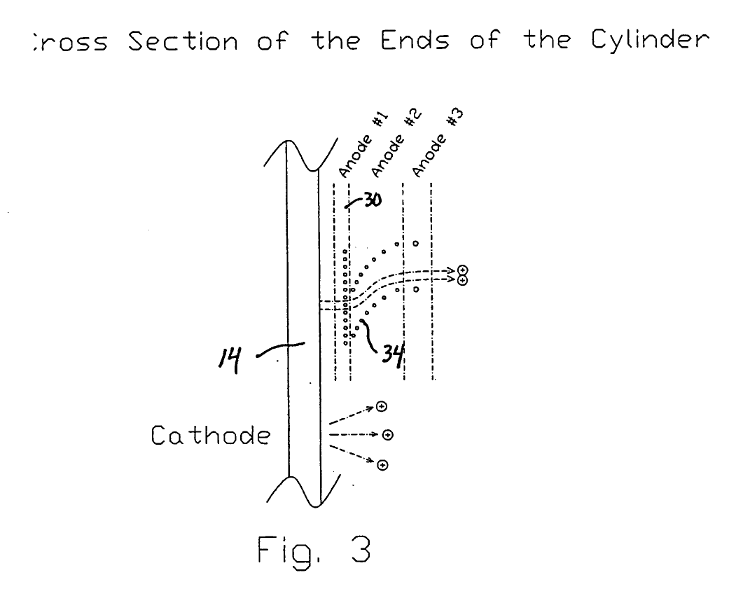

FIG. 4 is a diagrammatic view of a second embodiment of the apparatus of the present invention;

FIG. 5 is a diagrammatic view of an electrical supply system option for the apparatus of FIG. 4;

FIG. 6 is a perspective view of the anode structures of the apparatus of FIG. 4 in conjunction with a screening device;

FIG. 7a is a diagramatic view of the apparatus employing screening devices with the screening devices in an open position.

FIG. 7b is a diagrammatic view of the apparatus of FIG. 7a showing the screening devices in a closed position;

FIG. 8 is a cross-section schematic representation of a fuel cell made in accordance with the apparatus and process of the present invention;

FIG. 9 is a cross-sectional view of a fuel cell made with the apparatus and process of the present invention;

FIG. 10 is a cross-sectional view of a series of stacked fuel cells made with the apparatus and process of the present invention;

FIG. 11 is a diagrammatic view of an alternative apparatus of the present invention useful for manufacturing fuel cells.

### DETAILED DESCRIPTION OF THE INVENTION

The present invention relates to a process and apparatus for depositing thin films of material on selected substrates. The substrate to be coated can be of almost any material, such as metals, ceramic, plastic, glass, flexible sheets or combinations thereof. Similarly, the thin film material can be any solid metal or combinations of metals that are vacuum compatible. Examples of such metals are niobium, tantalum, hafnium, zirconium, titanium, chromium, nickel, copper, platinum, gold and silver. When ionized, the thin film material can also be combined with various reactive gases, containing for example, nitrogen, carbon or oxygen, to create compounds of nitrides, carbides, oxides and combinations thereof. The ionized thin film material can also be combined with inert gases, such as argon, to obtain a thin film material of high purity. Further, the thin film material can also be semi-conductive materials, such as carbon for the creation of various nanostructures and amorphous diamond films. The thin films can be coated on the substrate for a wide variety of purposes, such as to improve the catalytic reactivity of multiple deposition materials by depositing discrete particle sizes and amorphous or crystalline structures into very controlled interspersed structures. The process also has the ability to form more common crystalline nitrides for corrosion resistance, wear resistance, chemical resistance, abrasion resistance of the substrate, to add a decorative finish or improve the color or decorative characteristics of the substrate, or to shield against electromagnetic interference, radio frequency interference, electrostatic discharge, and impart improved conductivity, catalytic reactivity or reflectivity properties to the substrate.

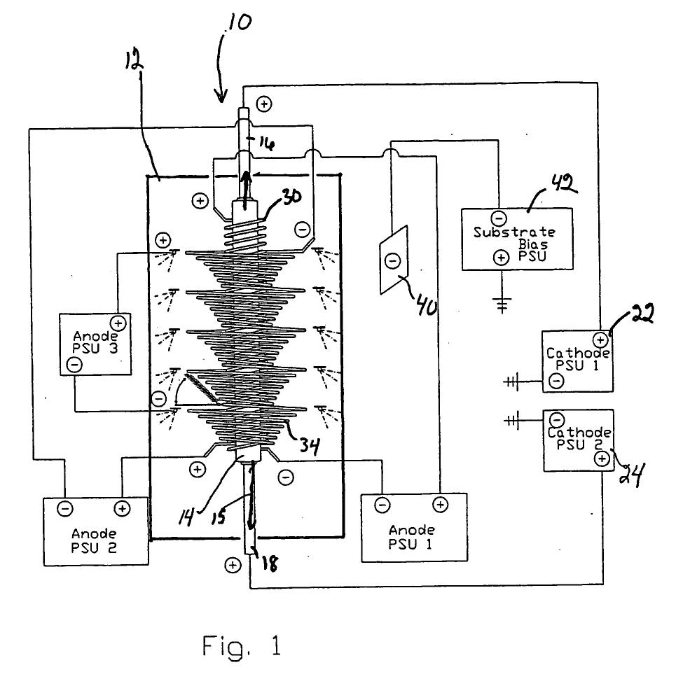

Turning now to FIG. 1, there is shown a general schematic of the ionic plasma deposition apparatus of the present invention. The apparatus 10 includes a vacuum chamber 12 which is pumped to a base pressure in the range of 10×10⁻⁵ Torr, to remove water vapor and provide an environment free of atmospheric gases and potential contaminants. A cathode 14 has a central axis 15 and is disposed near the center of the chamber. The cathode can be cylindrical, spherical, oval, rectangular or any elongated shape and is scalable to any length. The length is constrained only by the input power needed to run a very long source, which can be scaled up or down with the rest of the system. The cathode is used as the source for the material that is to be ionized and deposited on or impregnated into a selected substrate. Power supplies 22 and 24 are connected to the ends 16 and 18 of the cathode, respectively, and are either connected to multiple anodes or grounded to the vacuum chamber. The power supplies generate an arc for the ionization of the cathode material and are matched in current output and other electromagnetic characteristics.

The current from the power supplies 22, 24 is matched in such a manner so as to allow the resistivity of the cathode material to be the only variable for the precise removal of the cathode material and to determine where the arc will travel. The prior art has attempted to steer the arc faster and switch the directions of travel, with the detrimental creation of smaller macro-particles while decreasing larger macro particles. Extensive switching devices and sensors are not needed in this invention. The prior art switching and sensing devices cause uneven wear of the cathode, require constant calibration as the target size changes, need maintenance after minimal coating buildup and cause an improved yet inferior deposition uniformity compared to the present invention. The present invention relies on the varying resistivity of the cathode itself to drive the arc spot at high currents just past the point of the next arc split current. The arc split current is defined empirically for each material or alloy and results in the division of current density at the arc spots. The current level just below the splitting threshold releases the largest amount of macro particles and slows the arc travel on the surface considerably. The current level just above the splitting threshold causes the arc to spread over the surface of the target more evenly, move faster and release less macro particles due to the lower current density at each spot and the subsequent reduction in molten neutral particle material. Arc spot splitting occurs many times in the range of 10 amps to 1000 amps. This allows the power supplies to be precisely current controlled and monitored at this level just above the desired splitting current. As long as the power output is perfectly matched and not varied The change in internal resistance of the cathode material drives the arc in a greatly improved uniform path every where on the target. This resistance is determined by the current density buildup over a topographical feature on the cathode surface. As the arc spot removes material it moves to the next topographical high point in the plasma field. This movement torward the plasma keeps the arc from the ends of the target which are hidden from the exchange of charges in the plasma

This mode offers the advantage of higher currents with less neutral particle generation spread over more arc spot areas providing more uniformity and less molten material due to the improved smaller arc spots. This continuous action creates perfect uniformity of the deposited material and no wear pattern in the cathode, giving the best attainable target utilization over the entire length and radially in 360 degrees.

A first or inner anode 30 is in the form of an up and down structure adjacent to or encircling the length of the cathode. This structure generates a magnetic field stronger toward the center area of each anode component and changing directions at the ends. The anode causes the charged particles ejected from the cathode to form a trajectory between the anode components along the entire length of the cathode. A second or outer anode 34 is mounted along the length of the cathode to guide electrons and ions into a linear curved trajectory toward the substrate 40. The enhanced electromagnetic field creates a large area of uniform plasma constituent flow, which further enhances the arc spot travel while insuring uniform deposition at the substrate. The magnetic fields generated can be adjusted and the anode structures are modified to give any length of uniform deposition unconstrained by crossing helical magnetic fields that focus the plasma stream to small area on helical anodes.

The inner and outer anode structures 30 and 34 operate together to guide the charged particle flow toward the substrate and to screen macro-particles. The electromagnetic field of the multiple anode structures also causes the arc spot to run faster over the surface of the cathode causing more complete ionization of the cathode material with less formation of macro-particles if that is the desired mode of the apparatus. The apparatus can also be controlled to produce micro, nano and meso-particles of varying sizes by adjusting the relative strengths of the electromagnetic fields, adjusting the reactive gas and inert gas pressures and adjusting the screening effect of the anode structures.

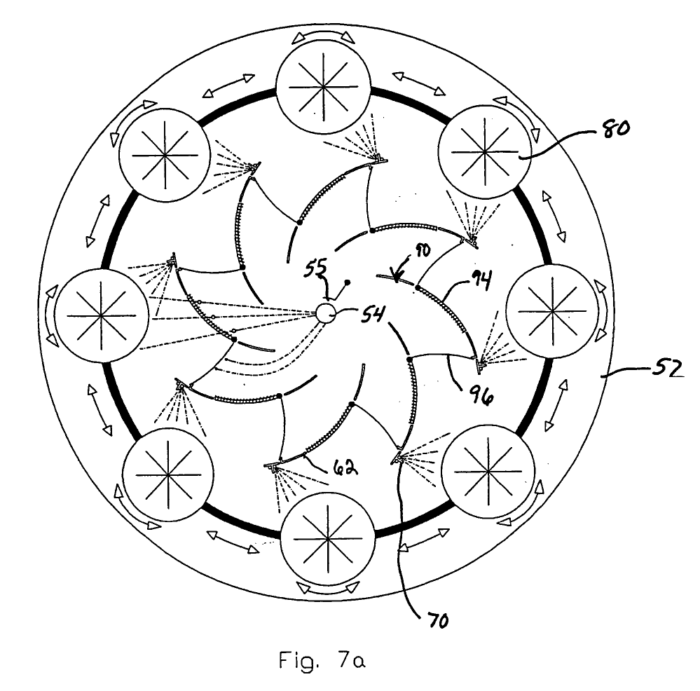

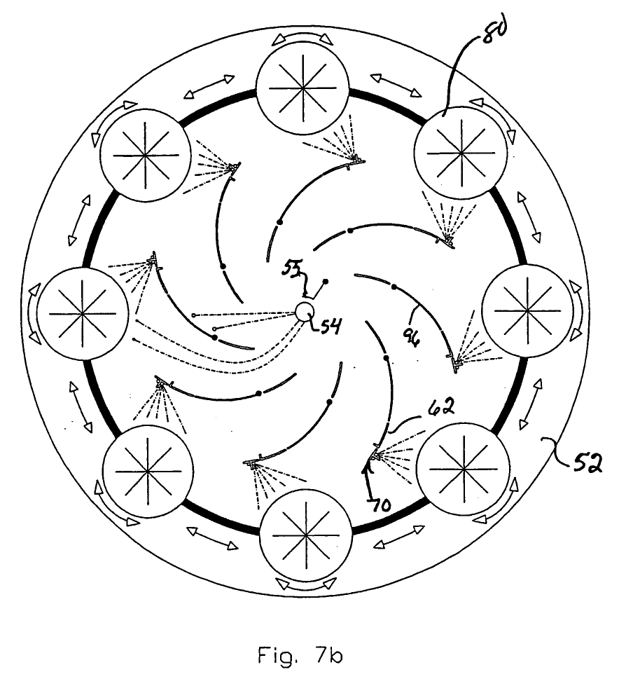

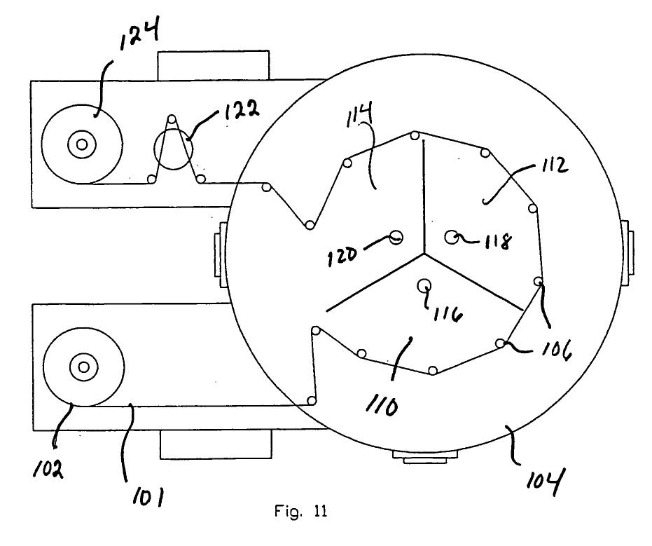

The substrate 40 to be coated is disposed about the cathode device at a distance to give continuous exposure to the uniform plasma controlled by the fields of the multiple anode structures. The substrate 40 is electrically isolated from the vacuum chamber and can be rotated or substrate material rolled with a variable bias voltage applied from a power supply 42 during the deposition process. Although only one substrate fixture is illustrated in FIG. 1, it will be appreciated that very large multiple substrates or articles to be coated may be arranged about the device at one time as illustrated in FIG. 7. It is also possible to provide multiple cathodes within a single, divided vacuum chamber (see FIG. 11) to refine the ability to control process parameters on two, three or more, discrete process steps at once for fuel cell applications, and large area rolls of multi-layer materials for many applications.

In operation, a plasma is generated by means of inputting energy of low voltage to the cathode from the power supplies. Voltages in the range of 10 to 50 volts are typical. An electric arc of variable current is generated between the anode coils and the cathode such that the arc spot is on the surface of the cathode. The arc vaporizes the cathode material into ionic particles and neutral particles, ejecting the particles radially toward the substrate or substrates to be coated.

The multiple coil arrangement of the present invention works well for many applications to limit the formation of macro-particles and to capture those that do form, while guiding the desired ionized particles to the substrate material. It has been found, however, that further control of the plasma constituents can be obtained through the use of specific anode structure arrangements and/or the employment of additional anode screen components and ground shield components. These additional components or arrangements allow the selection of specific constituent plasma particles or combinations of particles. The constituent particles which can be specifically selected include electrons, single and multiple ionized states of the target cathode materials, macro particles, micro particles, and nano structure particles, atomic neutral atoms and particles having specific particle conglomerate sizes. For example, possible combinations include a deposition comprising only nano particles or only neutral particles with no ions or electrons, as shown FIG. 7a Another example, which does not restrict the possible combinations is a deposition of only ionic materials and some electron flow as shown in FIG. 7b. Many other combinations of selected plasma constituents are also possible using the adjustable anode components of the present invention.

The selection of plasma constituents is achieved by arranging the anode structures or combinations of structures to obtain particular configurations of the electromagnetic fields generated by the anode structures. In addition, variably charged, mesh screen devices similar to those known in the art of plasma gun devices can be used in combination with the anode structures. By varying the sizes of the mesh screen employed, nano particle and macro particle control and flow alignment can be achieved.

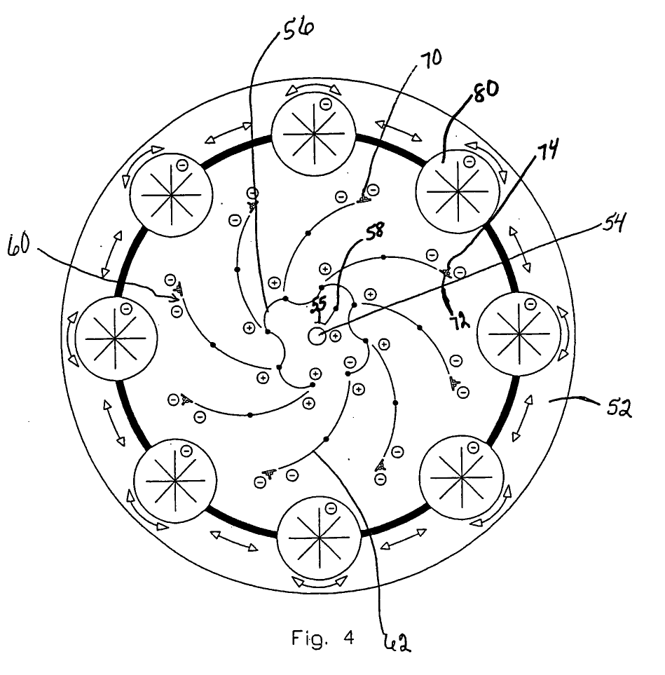

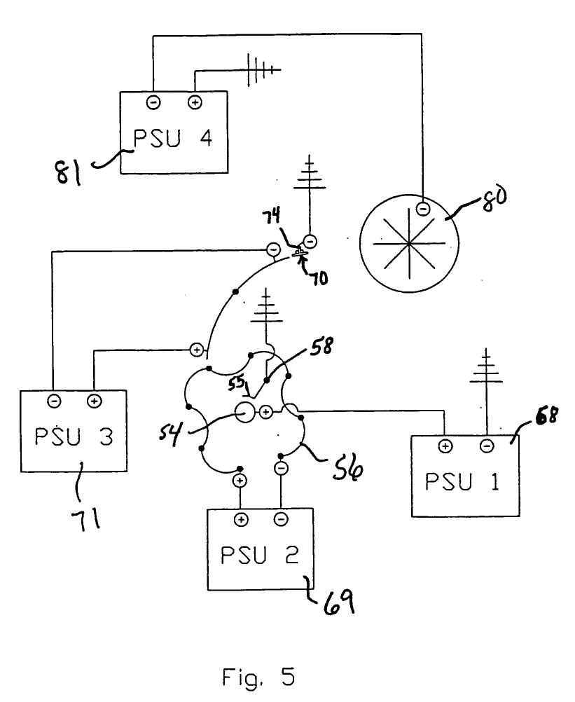

One embodiment illustrating a particular arrangement of anode structures is shown in FIG. 4. Referring to FIGS. 4-6, this embodiment includes a vacuum chamber 52 in which a cathode 54 comprised of target material is centrally disposed. Power from a power source 68 is supplied between the cathode 54 and a ground potential to generate an arc for the ionization of the cathode material into a plasma.

The arc is maintained or restarted by a bouncing striker 55 placed adjacent to the cathode. The bouncing striker 55 is a rod or wire formed from tungsten that is cantilevered from a hanger assembly. A gas manifold 58 is located adjacent the bouncing striker and supplies a high-pressure pulse or burst of argon gas to the free end of the bouncing striker. The high-pressure pulse pushes the striker into close proximity to the cathode surface so that the striker almost touches the cathode. The close proximity of the striker to the cathode ignites the arc. A sensor is used to detect any breakdown in the arc current and supply the required argon gas burst to regenerate or maintain the arc. This striker arrangement is an improvement over prior art mechanical devices used for maintaining an arc since such mechanical devices can break down and frequently need to be replaced or refurbished. It is also an improvement over gas burst devices which require a much higher local pressure to initiate the arc without a striker causing unstable gas dynamics during the deposition process. The bouncing striker action is constantly regenerated by the impact of material coming from the cathode causing it to oscillate in a predictable manner.

A first anode structure 56 is disposed about the cathode 54. This first anode structure 56 comprises a hollow tube formed into a series of connected loops 57, with each loop having a lower bent portion 57a, an upright straight portion 57b, and an upper bent portion 57c. The loops of the first anode are arranged so that the upright portions 57b of the loops are spaced apart from but together surround the cathode 54.

The first anode 56 is connected to a power source 69 which supplies a voltage in the range of 0 to 100 volts at 0 to 300 amps to generate an electromagnetic field between the cathode 54 and the first anode 56. The first anode can be made from any material that can carry the current load and generate an electromagnetic field. Copper, aluminum, stainless steel and other conductive metals are suitable anode materials. Cooling fluids such as water and/or glycol can be introduced into the hollow tube forming the first anode 56 to prevent the anode from over heating. The electromagnetic field generated by the first anode operates to confine energetic electrons from the plasma to the area immediately around or adjacent to the cathode, while helping to guide ions to a second anode 60. The electromagnetic field also helps to accelerate travel of the arc on the surface of the cathode.

The second anode structure 60 comprises a plurality of anode components 62, each of which is a series of connected loops 63 similar to the loops of the first anode. Also similar to the first anode, each second anode component is formed from a hollow tube of copper or other suitable material and can be fluid cooled.

Each second anode component 62 is positioned adjacent to an upright straight portion 57b of the loops of the first anode 56 and radiates outwardly from the straight portion 57b toward the wall of the vacuum chamber 52. As best shown in FIG. 4, each second anode component 62 curves as it extends toward the wall of the vacuum chamber. The second anode components 62 are electrically connected to each other and can either be connected to the power source supplying the first anode, or can be connected to a separate power source 71. Better control of the current and electromagnetic fields generated by the first and second anodes is achieved if the second anode structure 60 is connected to its own power source.

The power source for the second anode generates an electromagnetic field at each second anode component 62. In effect, the electromagnetic fields act as curved walls that cause the ionized particles and electrons to move in parabolic paths between two successive anode components 62. The anode components 62 have higher negative potential at their outer ends, causing the particles to accelerate as they travel between the two anode components. The result is a linear column of ionic material that reaches the substrates in a uniform trajectory dispersed over the entire length of the substrate. The improved dispersion of the present invention is due in part to the magnetic field lines of the second anode structures and the lack of constricting field lines along the top and bottom of the anode structure as seen in coil wound “filtered arc” prior art. The prior art teaches filtering of planar cathodes with multiple coils wrapped in a direction that is perpendicular to the cathode face that generates concentric competing field lines which spiral the charged particles into a focused beam. This arrangement does not permit the uniform deposition of large numbers of parts and large areas. The present invention uses ceramic structures at each end of the anodes that are floating with respect to the plasma potential.

Positioned adjacent to each outer end of each second anode component 62 is a third anode component 70. Each third anode component has a first upright panel portion 72 that is aligned with the end of a second anode component, and a second panel portion 74 extending perpendicularly from the center of the first panel 72 toward the vacuum chamber wall. Thus, the third anode components 70 are T-shaped in cross-section. The panel portions 72, 74 are made of copper or other suitable anode material and are joined together to form the T-shaped third anode component by brazing or any suitable means known in the art.

A cooling tube 76 is positioned at the inner right angle formed by the panels 72, 74, adjacent the end of the second anode component 62. The cooling tube 76 contains water or other cooling fluid for cooling the third anode component that is grounded or set to a predetermined bias to direct the electron flow. Positioned at the outer right angle formed by the panels 72, 74 is a gas jet manifold 78 for supplying argon, oxygen, nitrogen or other gas to this area of the vacuum chamber depending upon the desired material to be deposited. The gas jet manifold is preferably made of ceramic material due to heat buildup from the electron flow, however other materials could be used.

The third anode components 70 are electrically connected to each other and are at ground potential or other predetermined bias potential. These components function to attract electrons passing between the second anode components, and allow the ion particles to continue in their parabolic paths toward the substrate or substrates to be coated.

The substrates to be coated are positioned on turntables 80 which are arranged around the wall of the vacuum chamber 52. Each turntable has a central axis 82 and is rotatable around the central axis. The turntables can also rotate together around the wall of the vacuum chamber. Alternatively, the turntables can each rotate about their central axis while simultaneously rotating around the vacuum chamber. A negative bias voltage from a separate power supply 0.81 is applied to the turntables 80 and, consequently, to the substrates positioned thereon, so that the substrates are negatively charged with respect to ground.

The turntables are arranged so that a turntable is positioned in the pathway between two second anode components 62. This arrangement allows the substrates to be in the direct path of the ion particles exiting from between the second anode components. The ion particles accelerate toward the negatively charged substrate, thus coating the substrate with only the selected ion particles.

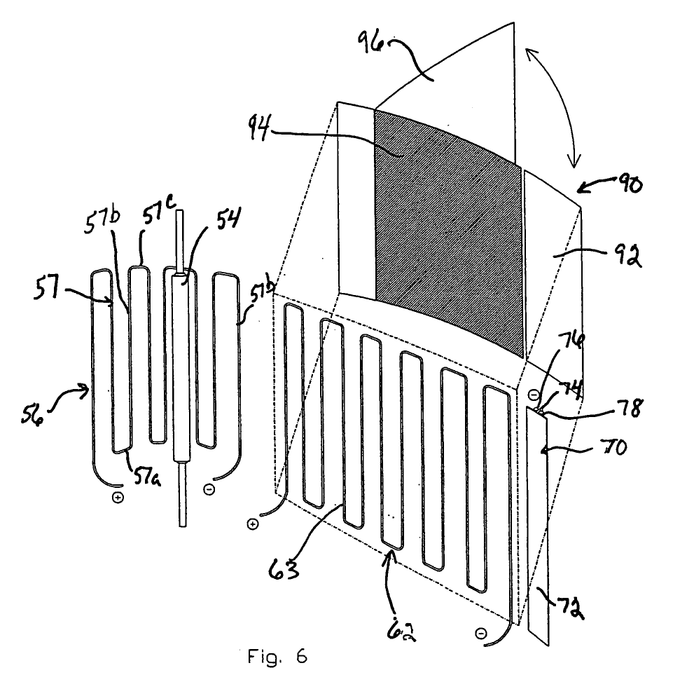

Control of macroparticle flow can be achieved by positioning a screening device at each second anode component of the embodiment shown in FIG. 4. This screening device is more clearly shown in FIGS. 6, 7a and 7b. The screening device 90 is mounted on ceramic standoffs and is positioned immediately adjacent the backside of the entire length of the second anode component 62. The screening device comprises a solid wall 92 interrupted by a central screen 94, which is preferably a mesh screen. The mesh size of the screen can vary depending upon the size of the particles desired to be controlled or allowed to pass through the screen. Immediately behind the screen 94 is a hinged solid gate 96 which is movable between a closed position, in which the gate is immediately adjacent the screen 94 and blocks the macroparticles that pass through the screen, and an open position, in which the gate 96 is moved away from the screen 94 to permit macroparticles to pass therethrough. This screen can be controlled and moved by any means known in the art For example, a chain drive can drive a drive gear mounted on the ceramic standoff to cause the gate 96 to move between its open and closed positions or in any position between open and closed. When the gate 96 of the screening device is closed, macroparticles impinge against the solid wall 92 and are precluded from reaching the substrate, as shown in FIG. 7b. If it is desired to permit some or all macroparticles to reach the substrate, the gate 96 can be opened, allowing macroparticles of a predetermined size to pass through the screen and contact the substrate. It will be appreciated that when the gate 96 is in the open position, as shown in FIG. 7a, its free end is near the next adjacent anode component 62. In this position, the gate 96 closes off the ion pathway between two second anode components 62, preventing ion particles from reaching the substrate while allowing only neutral particles of a desired size to reach the substrate by passing through the screen 94. Further control of the constituent plasma particles can be obtained by regulating and controlling the current supplied to the first, second and third anode components, 56, 60 and 70, respectively, to obtain electromagnetic fields of desired strengths.

The ability to select and control the plasma constituents enables the apparatus of the present invention to be used in the manufacture of materials in a wide variety of technologies. For example, the apparatus can be used in the manufacture of field emission devices, superconductor and semiconductor devices, magnetic devices, energy storage devices, catalytic devices, photovoltaic devices and electronic devices. One particularly useful application of the apparatus and process of the invention is in the manufacture of fuel cells. Thus, the present invention also includes a process for the manufacture of fuel cells.

In conventional methods of manufacturing fuel cells, each layer of the fuel cell stack is separately manufactured, and the layers are then bonded together. With the process and apparatus of the present invention, however, each layer of the fuel cell stack is deposited into the preceding layer, allowing uniform layers to be formed and integrated without the need for bonding layers or elaborate bonding technologies.

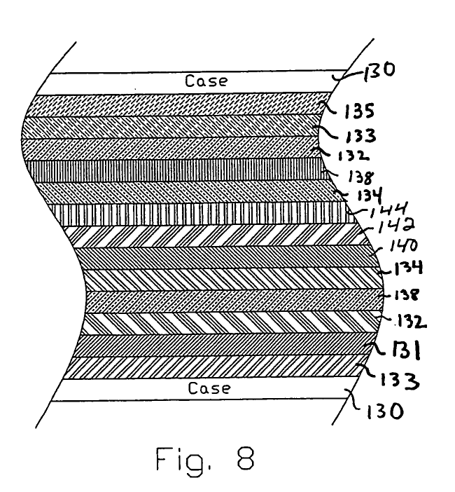

Referring to FIGS. 8-10, one embodiment of a fuel cell made by the plasma deposition process is shown. This embodiment comprises forming conductive layers and catalytic layers on a substrate 130, then forming a polymeric proton exchange membrane on the catalytic layer, and then forming additional catalytic and conductive layers on the polymeric proton exchange membrane. A liquid crystal polymer, (LCP) type plastic case having integrated porous LCP channels 131 that serve as a fuel channel 133 and an air channel 135 for the transport of fuel, air and water reactants is used as a substrate material. Such LCP cases can be molded, thermoformed or extruded. Other polymeric materials that can be molded or thermoformed can also be used as the substrate, such as polybutadiene (PBD) and polyethylene. The substrate is placed or spooled through the deposition apparatus such as the apparatus illustrated in FIG. 4. A carbon layer 32 in the form of graphite, carbon nanotubes, diamond-like carbon, or combinations thereof is deposited on the LCP plastic substrate to enhance the catalytic reactivity of the catalyst or as an electron conductive anode. The carbon layer is deposited by placing a cathode of carbon material in the vacuum arc deposition apparatus, then vaporizing the carbon target material and depositing the carbon particles on the LCP plastic substrate in the desired particle size and dispersion. The carbon particles can be deposited on one side or the other side of the substrate, or can be deposited on both sides simultaneously.

Thereafter, a catalytic metal layer is deposited into the carbon layer 132 by placing a cathode of the desired metal into the deposition apparatus, then vaporizing the target metal and depositing metal particles of a desired size on the carbon layer. Increased catalytic activity can be obtained if discrete neutral particle sizes in the nanoparticle range are deposited. The catalytic metal or alloy can be any Group VIII metal or oxide or a combination of any metal. For most fuel cell applications however, the catalytic metal is Pt or an alloy thereof, or Ru-Pt or an alloy thereof, which may also include one or more other metals or oxides from Group VIII of the periodic table or other groups as needed to increase the catalytic efficiency. Good results can be obtained with the deposition of a Ru-Pt type catalyst plus group VIII oxides layer 134.

Either before or following the catalytic metal layer, a porous layer 138 of gold, carbon or other conductive material is deposited to enhance electron flow through the fuel cell. This layer is similarly formed by placing a cathode of the gold, carbon or other conductive material into the vacuum arc deposition apparatus, then vaporizing the target cathode material and depositing the material onto the catalytic metal layer.

A solid polymer membrane layer or layers 140, 142 and 144 are deposited on the porous conductive layer by introducing reactive gas (es) into a section of the vacuum chamber and using a plasma to polymerize the gases to form and deposit the solid polymer membrane layer 145. The reactive gases used are, for example, trifluoromethyl sulfonic acid, or a chlorotrifluoroethylene composition. These gases may be used in combination with other hydrocarbon gases such as methane. Typical gas flow pressures of 2 to 10 mT are used. The solid polymer membrane has protonic conductivity and functions as a proton exchange membrane in the fuel cell.

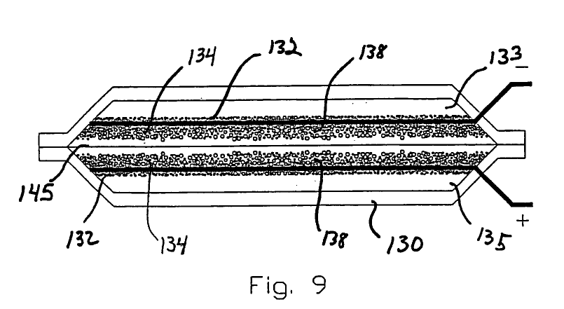

The formation of catalytic metal layers 134 and conductive carbon layers 132,138 can be repeated on the solid polymer membrane to form a structure having catalytic metal and conductive carbon layers on each side of the solid polymer proton exchange membrane. Although the layers 132-150 are shown in FIG. 8 as discrete layers for illustration purposes, it will be appreciated that each successive layer can be dispersed into the preceding layer, resulting in a fuel cell having integrated layers, as shown in FIG. 9. In an alternative embodiment, instead of repeating the process of forming the catalytic metal and conductive carbon layers on the proton exchange membrane, the substrate can be folded over after the formation of the proton exchange membrane layer so that the polymer membrane layers meet, as shown in FIG. 9, and the edges of the substrate sealed to form the fuel cell. This folding of the substrate has the advantage of aligning the two sides of the complete cell if the sides are to have layers of identical consistency on either side of the polymer membrane.

Although the deposition apparatus can be operated with a single cathode of the desired target material, more efficient operation of the apparatus for fuel cell applications and others can be achieved if the vacuum chamber is divided into three or more sections, with each section being supplied with a target cathode for depositing the respective layers of carbon, catalytic metal, and conductive material. An embodiment of the apparatus employing three or more separate cathodes is shown in FIG. 11, in which the anode structures have been removed for clarity. In this embodiment, the substrate 101 is in the form of a sheet which is unwound from a roll or spool 102 and fed into the vacuum chamber 104. A plurality of rollers 106 are spaced about the vacuum chamber and convey the sheet material around the vacuum chamber through three or more separate deposition stations 110, 112 and 114, respectively. The first station 110 employs a cathode 116 of, for example, graphite material to deposit a carbon layer. The next station 112 employs a cathode 1-18 of, for example, the desired catalytic metal to deposit a catalytic layer on the carbon layer. The third station 114 employs a cathode 120 of, for example the desired conductive material to deposit a conductive layer on the catalytic layer. The substrate is then advanced to a plasma polymerization/sulfonization area 122 where the polymeric proton exchange membrane is deposited. The substrate can then be wound onto a take up roll or spool 124, or the deposition process can be repeated depending on the cell specifications. An alternative, embodiment of the present invention allows the economical spooling of the substrate and flipping the substrate sheet to the other side decreasing equipment and target material costs. Gold or other conducting materials can be deposited inexpensively before the carbon to increase conductivity.

In general, the deposition process can be accomplished from any direction in relation to the complete fuel cell stack, and either end can be the substrate. The apparatus can also be operated in a configuration allowing only macro particles to be deposited and the size of the macro particles to be controlled by the process parameters. An application of this mode is to create nanostructures with high surface areas of dispersed catalyst of varying particle sizes to optimize the reactivity efficiency in the fuel cell. A nano structure of carbon can be followed by a discretely sized particle dispersion of platinum followed by another particle size and dispersion of ruthenium followed by an amorphous continuous film of gold for electron conduction. Other embodiments include using a previously molded or extruded polyethersulfone ionic conductive polymer as a substrate proton exchange membrane and depositing the catalytic metal and conductive carbon layers on both sides of the polymer substrate simultaneously or in succession.

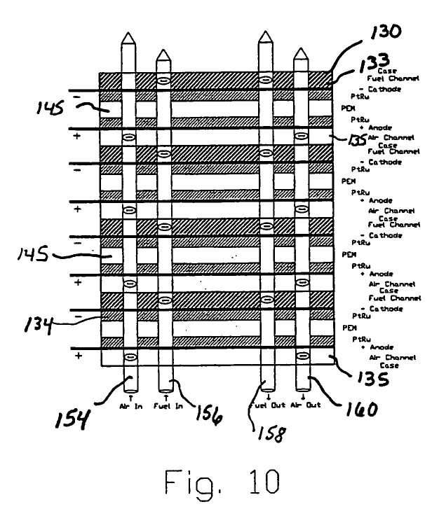

The individual fuel cells can be stacked as multiple cells in a configuration that allows for the continuous inter layering and stacking of the fuel, air and water channels to form common manifolds. Such fuel cell stack is illustrated in FIG. 10. Inlets 154, 156 for the introduction of air and fuel, respectively, to the fuel cell, and outlets 158, 160 for exhausting fuel and air, respectively, from the fuel cell can be inserted through the fuel stack layers following assembly of the stack. Each fuel cell or combination of fuel cells can be heated ultrasonically or overmolded to seal the ends of the cells and add structural integrity to the fuel stack.

The following example is illustrative of the process for making the fuel cell. A substrates of LCP, is deposited with carbon nano-particles of 5 to 10 nanometers using the apparatus similar to FIG. 7. For the deposition process, current is supplied to the first anode at 0 to 50 amps, current to the second anode structure is at 50 to 150 amps, and the third anode is at ground potential. The current to the cathode is at 240 amps and the gas pressure of the vacuum chamber is 7.0×10⁻⁴ Torr. Dispersed catalyst nano-particles of Pd, Pt, Ru are then deposited onto the carbon under process conditions similar to those used for the carbon, with the parameters adjusted for smaller particle sizes to increase catalyst reactivity. The ionomeric layer and the sulfonation are accomplished with a pulsed 13.56 MHZ RF plasma polymerization power of 5 to 100 watts at a pressure of 2 to 10 mT. A fluorocarbon gas commercially available from Praxair and a sulfonic acid solution available from VWR Scientific are introduced through a mass flow controller set for 30 sccm producing a perfluorinated proton exchange membrane.

The use of the present invention to form the different layers of an integrated fuel cell allows the fuel cell to be manufactured on a very large scale using a continuous process. Moreover, the process gives greater adhesion, better corrosion resistance, more power per volume, less crossover of fuel and greater ion exchange efficiencies due to the precise formation of layers with the precise amounts of metal catalyst, conductive material, and proton exchange ionomeric material.

While the present invention has been described with references to specific embodiments thereof, it should be understood by those skilled in the art that various changes and modifications may be made and equivalents may be substituted without departing from the true spirit and scope of the invention. All such modifications are intended to be within the scope of the appended claims.

1. A plasma deposition apparatus for applying one or more thin film materials into or onto a substrate by selectively controlling the depositing plasma constituents that will reach a substrate from a cathode, the apparatus comprising:
(a) a vacuum chamber,
(b) a cathode disposed within said vacuum chamber comprised of a target material, said cathode being powered to generate an electric arc to create said plasma of constituent particles;
(c) at least one first anode disposed within said vacuum chamber for generating an electromagnetic field between said cathode said first anode to guide the flow of charged constituent particles;
(d) at least one second anode structure positioned adjacent to said first anode, said second anode generating an electromagnetic field to direct said charged constituent particles to the substrate for deposition;
(e) at least one wall and screen positioned adjacent to said second anode to control flow of neutral constituent particles to the substrate.

2. The apparatus of claim 1 wherein a moving gate is provided adjacent to said screen to allow adjustable control of selected constituent particles to the substrate.

3. The apparatus of claim 1 wherein a third anode is positioned adjacent the second anode, the third anode generating a third electromagnetic field that cooperates with the electromagnetic fields generated by the first and second anodes to control electron flow.

4. The apparatus of claim 1 further comprising at least one gas manifold positioned within the vacuum chamber to supply a gas to the vacuum chamber.

5. The apparatus of claim 1 further comprising at least one fixture disposed within the vacuum chamber for mounting the substrate thereon.

6. The apparatus of claim 5 wherein the fixture is energized by a variable bias voltage applied by a separate power source.

7. The apparatus of claim 1 wherein the second anode structure comprises a plurality of second anode components, each of which radiates outwardly from said first anode toward the vacuum chamber wall.

8. The apparatus of claim 7, wherein a wall and screen component is positioned adjacent each of the second anode components.

9. The apparatus of claim 8, wherein the screen is provided with a hinged solid gate which is moveable between an open and a closed position to control the neutral particle flow to the substrate.

10. The apparatus of claim 1, further comprising a striker rod cantilevered into a position adjacent the cathode and a gas manifold supplying a gas to the striker rod, whereby a gas pulse from the gas manifold moves the striker rod into close proximity to the cathode to ignite the arc at the cathode.

11. The apparatus of claim 1, wherein the first anode comprises a series of connected loops surrounding the cathode.

12. A plasma deposition apparatus for applying one or more materials into or onto a substrate by selectively controlling the depositing plasma particles that will reach the substrate from a cathode, the apparatus comprising:
(a) a vacuum chamber,
(b) a cathode disposed within the vacuum chamber comprised of a target material, the cathode being powered to generate an electric arc to create a plasma of constituent particles;
(c) at least one first anode disposed within the vacuum chamber for generating an electromagnetic field, between the cathode and the first anode to guide flow of the charged constituent particles;
(d) at least one second anode structure positioned adjacent to the first anode, the second anode generating an electromagnetic field to direct the charged constituent particles to the substrate for deposition;
(e) at least one wall and at least one screen positioned adjacent to the second anode to control flow of neutral constituent particles to the substrate;
(f) at least one third anode structure positioned adjacent one end of the second anode structure, the third anode structure generating an electromagnetic field to control flow of electron constituent particles.

13. The apparatus of claim 12, wherein the second anode structure comprises a plurality of second anode components, each of which radiates outwardly from the first anode toward the vacuum chamber wall.

14. The apparatus of claim 13, wherein the screen is provided with a hinged solid gate which is moveable between an open and a closed position to control flow of neutral constituent particles to the substrate.

15. The apparatus of claim 12, further comprising a striker rod cantilevered into a position adjacent the cathode and a gas manifold supplying a gas to the striker rod, whereby a gas pulse from the gas manifold moves the striker rod into close proximity to the cathode to ignite the arc at the cathode.

16. A plasma deposition process for applying selected target material particles vaporized from a cathode of the target material into or onto the surface of a substrate, the process comprising
(a) mounting the cathode and the substrate in spaced apart relation in a vacuum chamber;
(b) providing within the vacuum chamber at least one first anode structure which surrounds the cathode, at least one second anode structure positioned adjacent the first anode structure, and a wall component comprising a screen with an adjustable opening positioned adjacent to the second anode;
(c) powering the cathode to generate an electric arc to create a plasma of constituent target particles, including charged particles;
(d) generating an electromagnetic field between the cathode and the first anode to guide the flow of the charged particles;
(e) generating an electromagnetic field around the second anode structure to direct the charged particles to the substrate; and
(f) adjusting the openings of the screen to control flow of neutral particles to the substrate.

17. The process of claim 16, wherein the substrate is mounted on a fixture energized by a variable bias voltage and the fixture is rotated about its central axis.

18. The process of claim 16, wherein the electromagnetic field between the cathode and the first anode is generated by supplying a current in the range from 0 to about 100 volts at 0 to about 300 amps to the first anode.

19. The process of claim 16, wherein the vacuum chamber is provided with a third anode structure and an electromagnetic field is generated around the third anode to capture electrons from the plasma material.

20. A process for manufacturing a fuel cell comprising conducting the following steps on a selected substrate in a vacuum chamber:
(a) depositing a carbon layer on the substrate by vaporizing a cathode of graphite material into a plasma of constituent particles and guiding the particles to the substrate with electromagnetic fields generated by at least a first anode and a second anode;
(b) depositing a micro-particle metal catalyst layer on the carbon layer by vaporizing a cathode of metal material into a plasma of constituent particles and guiding the constituent particles to the substrate with the electromagnetic fields generated by the at least first and second anodes;
(c) introducing a reactive gas into the vacuum chamber and forming a solid polymer membrane layer on the metal catalyst layer; and
(d) repeating steps (a) and (b) to form the fuel cell.
